(19) United States
(12) Patent Application Publication
(10) Pub. No.: US 2008/0251376 A1
(43) Pub. Date: Oct. 16, 2008

(54) Vacuum Processing Device and Method of Manufacturing Optical Disk

(75) Inventors: Yoji Takizawa, Kanagawa (JP); Jiro Ikeda, Shizuoka (JP)

Correspondence Address: BANNER & WITCOFF, LTD., 1100 13th STREET, N.W., SUITE 1200, WASHINGTON, DC, 20005-4051, US

(73) Assignee: SHIBAURA MECHATRONICS CORPORATION, Yokohama (JP)

(21) Appl. No.: 11/579,881

(22) PCT Filed: May 16, 2005
(86) PCT No.: PCT/JP2005/008881

§ 371 Date: Nov. 8, 2006

(30) Foreign Application Priority Data
May 17, 2004 (JP) 2004-146416

(51) Int. Cl. C23C 14/34

(52) U.S. Cl. 204/192.15; 204/298.09

(57) ABSTRACT

To provide a vacuum treatment device capable of reducing the occurrence of the tilt and deformation of treated materials by suppressing the heating of a substrate by continuous spattering in a vacuum. This vacuum treatment device is characterized by comprising a main chamber capable of being vacuated in a vacuum state, a load lock mechanism carrying disk-like treated materials into and out of the main chamber while holding the vacuum state of the main chamber, a horizontal rotary carrying table disposed in the main chamber, having a plurality of susceptors exchanging the disk-like treated materials with the load lock mechanism for mounting, rotated about a rotating shaft, and forming a carrying route for the disk-like treated materials, a plurality of film-forming chambers for forming a multi-layer film on the disk-like treated materials disposed in the main chamber along a circumference about the rotating shaft and carried by the rotary carrying table, and cooling mechanism disposed between the film-forming chambers and cooling the disk-like treated materials.

### FIELD OF THE TECHNOLOGY

The present invention relates to a vacuum processing device depositing continuously a multilayer film on a substrate of such as an optical disk or an optical component, and a method of fabricating optical disks.

### DESCRIPTION OF THE BACKGROUND TECHNOLOGY

Optical disks such as the compact disk (CD) or the digital versatile disk (DVD) have been diversified recently, and therefore availability thereof has been still growing from an information medium of reading-only to an optical information medium capable of writing. Synthetic resin, typically polycarbonate, having a low mold shrinkage ratio or a low expansion coefficient is used for materials of the disk substrate. Information is recorded on the surface of the substrate as a pit row in the case of the read-only disk, and a guide groove to become a track for laser is formed on the surface of the substrate in the case of the disk capable of writing. A multilayer film containing a writing layer is deposited on the surface in order to constitute the disk.

In FIG. 16, is shown a structure of the typical writable optical disk in which a guide groove 101a guiding a laser beam from an optical head is formed on one surface of a transparent polycarbonate substrate 101 of 0.6 mm in thickness, then a first dielectric material layer 102, a phase change writing layer 103, a second dielectric material layer 104 and a reflection layer 105 are deposited on the surface in this order, and further a UV-cured overcoat layer 106 is coated thereon. The optical disk of approximately 1.2 mm in thickness is obtained by laminating the multilayer substrate and another polycarbonate substrate 110 of 0.6 mm in thickness through a lamination adhesive layer 107.

The multilayer film is constituted of a dielectric material layer, a writing layer and a reflection layer, which are deposited by sputtering. However, the dielectric material layer takes longer to obtain the same thickness as the metallic layer because film-depositing efficiency thereof by sputtering is low compared to the metal. The multilayer film is deposited continuously by passing sequentially in order through a plurality of film-depositing chambers which sputter respective layers, so that multilayer film-depositing tact is limited by a film-depositing chamber that takes the longest time for film-depositing.

FIG. 17 shows an example of conventional vacuum processing devices for film-depositing, where (a) is a schematic plan view and (b) is a schematic cross sectional view along the line A-A. The main chamber 120 capable of being evacuated in a vacuum state is provided with a load lock mechanism 121, and furthermore first to fourth film-depositing chambers 122, 123, 124 and 125 are positioned together with the load lock mechanism 121 along a circumference in the main chamber so as to be located on each vertex of a regular pentagon. A rotary table 126 is located at the center of the main chamber 120, and rotates intermittently on a shaft 127 having an exhaust hole in a horizontal-plane. The disk substrate 101 sent from the load lock mechanism 121 is transported to the first film-depositing chamber 122, and the first dielectric material layer 102 is deposited thereon by sputtering. Then, the disk substrate 101 is transported to the second film-depositing chamber 123 where the writing layer 103 is deposited thereon. Thereafter, the second dielectric material layer 104 and the reflection layer 105 are sequentially deposited by the film-depositing chambers 124 and 125. The disk substrate 101 then returns to the load lock mechanism 121 and is taken out of the main chamber 120. The UV-cured overcoat layer 106 is coated on the multilayer-deposited substrate which is taken out. An optical disk is obtained by laminating the multilayer-deposited substrate and another polycarbonate substrate 110 of 0.6 mm in thickness through the lamination adhesive layer 107.

In the case of continuous film-depositing in a vacuum like this, temperature rising due to the heat of plasma discharge at the film-depositing process cannot be effectively diminished by cooling the substrate, so that temperature of the substrate rises each time it passes through every film-depositing chamber. For instance, the temperature of a substrate in 25 degrees Celsius rises to 100 degrees Celsius after film-depositing. It has been hitherto proposed that the disk substrate awaits during a certain time in the load lock chamber after film-depositing so as to be slowly cooled (e.g. Patent Document 1). When awaiting in the vacuum processing device like the above, i.e. cooling the substrate during this process is tried by means of stopping any one of the film-depositing chambers, e.g. the third film-depositing chamber 124, the temperature of the substrate must be sharply changed before and after the stopped film-depositing chamber for the post-processes in order to cool it sufficiently by one tact time. If the multilayer film is deposited on the condition that the temperature of the substrate is largely different, stress-strain is generated in the multilayer film. Therefore, the stress-strain gives a strain to the multilayer film-deposited substrate taken out from the main chamber, and results in generating a warp of the substrate called ‘tilt’. An internal strain of the polycarbonate substrate itself molded by a stamper is further added thereto. Because extent of ‘the tilt’ is not uniform for every substrate and deformation occurs, the problem is to decrease these factors. For example, permissible ranges of the tilt for the optical head utilizing a laser having the wavelength of 640 nm are to be within 0.8 degree for radial tilt and within 0.3 degree for tangential tilt, so that even a warp of μm unit of the disk may be a cause of some trouble.

Moreover, quickening the tact time is required to improve the efficiency of mass-production. Aiming at shortening the time of sputtering process in each film-depositing chamber requires increment of electric power for sputtering. As a result, rising of temperature of the substrate in each process becomes more remarkable, and results in increasing the cause of the tilt. Patent Document 1: Japanese Patent Laid-Open No. 2003-303452

### DISCLOSURE OF THE INVENTION

### Problems to be Solved by the Invention

The present invention is intended to suppress rise of the temperature of a processed object due to the heat generated by continuous sputtering in a vacuum, and to obtain a vacuum processing device diminishing generation of the tilt or deformation in the processed object. The present invention is further intended to obtain an optical disk having a tilt or deformation being minor.

### Means to solve the problems

An aspect of the present invention is as follows.

(1) A vacuum processing device comprises:

a main chamber capable of being evacuated in a vacuum state;

a load lock mechanism carrying a processed object into and out of the main chamber while holding the vacuum state of the main chamber;

a rotary carrying table disposed in the main chamber, and forming a carrying route for the processed object;

a plurality of film-depositing chambers for depositing a film in a multilayer-shape on the processed object, disposed in the main chamber along a circumference about the rotating shaft; and

cooling mechanisms disposed between respective film-depositing chambers, and cooling the processed object.

(2) The cooling mechanism is disposed between the load lock mechanism and the film-depositing chamber.

(3) When the carrying route is a trace of the center of the processed object to be carried, the carrying route by rotation of the horizontal rotary carrying table traces a certain circle, and the load lock mechanism, the film-depositing chamber and the cooling mechanism are disposed at an interval of a certain angular distance about the rotating shaft along the circle.

(4) The film-depositing chambers are disposed on a first circumference with a central portion thereof at the rotating shaft of the rotary carrying table, and the cooling mechanisms are disposed on a second circumference, wherein the second circumference is different from the first circumference with respect to radii thereof.

(5) A susceptor carrying the processed object is disposed on the rotary carrying table, and the susceptor is movable between the first circumference and the second circumference on the rotary carrying table in a radial direction thereof.

(6) The cooling mechanism contains a cooling chamber.

(7) In the main chamber, an area occupied by one of the cooling chambers is smaller than an area occupied by one of the film-depositing chamber.

(8) The cooling mechanism is provided with a cooling chamber, and capable of isolating hermetically from a space of the main chamber.

(9) A susceptor carrying the processed object is disposed on the rotary carrying table, and the susceptor is lifted by a susceptor-pusher and pressed on an opening wall of the cooling chamber so as to come to be hermetically sealed.

(10) The cooling mechanism includes an inlet portion introducing a gas into the cooling chamber and acting as a heat conducting member from the processed object.

(11) A cooling member having a cooling surface is provided in the cooling chamber.

(12) Each of the cooling chambers is capable of setting a temperature individually.

(13) The processed object on which a film is deposited by the film-depositing chamber is a disk-like processed object having a substrate of synthetic resin.

(14) The present invention is characterized by a manufacturing method of an optical disk, wherein a multilayer film is obtained by depositing continuously sputter-deposited films on a disk substrate of synthetic resin upon executing a plurality of sputtering processes in an evacuated atmosphere, characterized in that a cooling process is inserted between all the sputtering processes in order to maintain a temperature of the substrate to be 50 degrees Celsius maximum.

### EFFECT OF THE INVENTION

A vacuum processing device capable of suppressing the tilt or deformation of the processed object carried out of the device can be realized upon suppressing rise of the temperature of the processed object due to reservation of heat thereby caused by the heat generated by continuous sputtering in a vacuum and depositing a sputtered film on the processed object always maintained at a predetermined low temperature.

In the present invention, ‘vacuum’ means a state that is depressurized to a pressure lower than the atmospheric pressure, and ‘vacuum processing’ means carrying out film-depositing by sputtering and cooling processing at a reduced pressure.

### PREFERRED EMBODIMENTS TO CARRY OUT THE INVENTION

The present invention is to maintain the temperature for film-depositing on the processed object within a predetermined range by disposing a cooling mechanism between respective film-depositing chambers in a main chamber having a plurality of film-depositing chambers. Starting of film-depositing in each chamber can be controlled at the optimum temperature. Referring to the drawings, embodiments of the present invention will be explained hereinafter.

FIG. 1 to FIG. 7 show an embodiment of the present invention. As shown in FIG. 1, a load lock mechanism 20, four film-depositing chambers 30a to 30d, and five cooling mechanisms 40a to 40e are disposed in a main chamber 10 capable of being evacuated to a vacuum state suitable for discharge, e.g. 10⁻¹ Pa or less along a circumference c centered at the vicinity of the main chamber so as to be disposed at the interval of the angle which is the division of the circumference divided by ten. The cooling mechanisms 40a to 40d are disposed at a position between the film-depositing chambers 30a to 30d and the load lock mechanism 20 respectively. On the bottom portion 13 of the main chamber 10, pushers 11 pushing up susceptors to be described hereafter are disposed in such a manner that each pusher is in alignment with the positions of the load lock mechanism, the film-depositing chambers and the cooling mechanisms at an interval which is divided into ten equal divisions of a circumference, and are driven vertically by a pusher driver portion 11a.

In the main chamber, a horizontal rotary carrying table 50 whose axis 51 is positioned at the center of the chamber is disposed in order to carry a disk substrate on which a multilayer film is deposited, from the load lock mechanism to each film-depositing chamber and cooling mechanism. An exhausting path 53 is deposited in a rotating shaft 52 horizontally rotating intermittently in the direction of the arrow and connected with a rotation driver portion 54 and an exhaust system 55.

As shown in FIG. 2 and FIG. 3, the carrying table 50 is connected with the center of the table base member 56 through the rotating shaft 52, and carries a plurality of susceptors 57a to 57j along a circumference centered at the axis 51 disposed at the interval of the angle divided equally by ten, which corresponds to the arrangement of the load lock mechanism, each film-depositing chamber and each cooling mechanism. The susceptor carries the disk substrate 101, which is a processed object, and also acts as a valve lid member of the load lock mechanism, each film-depositing chamber and each cooling mechanism. At the position of the table base member 56 where each susceptor 57a to 57j is placed, an opening 50a is formed so as to penetrate the pusher 11 that is driven vertically by the pusher driver portion 11a pushing up the susceptor from the table base member.

As shown in FIG. 2, the film-depositing chambers 30a to 30d are provided with a target 31, which is the material to be sputtered, at the top of the chamber. The bottom of the chamber is open and the opening 33 is hermetically pressed by the susceptor 57 through the pusher 11 so as to dispose the disk substrate 101 carried by the susceptor on the opening 33. Thereby, the inside of the film-depositing chamber can be controlled in order that the pressure thereof may become a pressure suitable for sputtering by means of an exhaust pump 32 for the film-depositing chamber, the pressure above being different from the pressure in the working space of the carrying table of the main chamber. Sputtering is carried out by supplying a voltage of direct or alternate current between the electrode of target side and the electrode located in the vicinity of the disk substrate, to collide ions generated by grow discharge in the film-depositing chamber with the target, which is deposited on the disk substrate so as to form a layer. The disk substrate is heated and the temperature thereof rises in this process.

Further explanation about the cooling mechanism and the susceptor will be executed next. In FIG. 4, a through-type opening to become the cooling chamber 41 is formed in a thick top plate 12 of the main chamber 10 and the outside of the chamber is hermetically sealed with an outer lid member 42 having a seal 42a of O-ring formed on the periphery thereof. A cooling liquid-supplying pipe 43a and a cooling liquid-discharging pipe 43b penetrate the outer lid member 42, and fix a cooling plate 43 inside the cooling chamber. A cooling liquid passage is formed in the cooling plate. A cooling liquid such as water supplied from the cooling liquid-supplying pipe 43a passes through the cooling plate 43 and then is discharged via the cooling liquid-discharging pipe 43b, thereby cooling the cooling plate. In addition, the outer lid member 42 is provided with a cooling gas-feeding pipe 44 to supply a cooling gas for conducting the heat from the processed object into the cooling chamber.

The susceptor 57 placed on the carrying table base member 56 is positioned above the opening 50a of the base member, and held movable vertically at the periphery of the opening through a guide pin 59. The susceptor 57 is constituted of a susceptor base 60 fixed to the base member 56 and a dish-like disk substrate holder 62 supported by a pillar portion 61 provided at the center of the top surface of the stand, and a stopper 63 to fix the disk substrate is formed at the periphery of the holder 62. The seal portion 64 of O-ring is provided at the top periphery of the susceptor base 60.

The pusher 11 is attached to the bottom portion 13 of the main chamber corresponding to the cooling chamber 41 so as to move vertically along the wall of the chamber with a hermetically evacuated state. When the pusher 11 rises in the direction of the arrow as shown in FIG. 5, the susceptor 60 is pushed up. Then, the disk substrate 101 to be the processed object is introduced into the cooling chamber 41, and the susceptor base is pressed against the bottom surface 12a of the top plate 12 around the periphery of the cooling chamber. With joining hermetically the bottom surface 12a of the top plate to the seal portion 64 of the susceptor base, the cooling chamber is isolated hermetically from the space of the main chamber. In this condition, helium gas (He) is introduced and fills the cooling chamber in order to force the heat to be conducted between the cooling plate 43 and the disk substrate 101.

The pusher 11 descends in the direction of the arrow as shown in FIG. 6, the susceptor 57 is separated from the cooling chamber and returns onto the table base member 56. Simultaneously, the cooling chamber 41 is opened to the main chamber side, and the cooling gas is stopped. Released gas is diffused in the space of the carrying table and exhausted from the exhaust system 55. It is also possible that the outer lid member 42 is provided with a cooling gas-retrieving pipe to retrieve the cooling gas. Because the width of the cooling chamber may be a size that can pass the disk substrate, the chamber can be formed with a diameter slightly larger than 120 mm if the disk substrate is used for the DVD disk of 120 mm in diameter. The height thereof is sufficient to be the thickness of the thick top plate 12, so that the cooling chamber can be formed smaller than the film-depositing chamber with respect to the diameter. Though the cooling plate 43 is preferably formed in a disk-shape in compliance with the disk, the disk-shape is not necessarily indispensable. Similar effect can be obtained upon rotating the disk holder 62 by making the cooling plate a rectangle or a semicircle whose area is smaller than that of the disk.

Referring to FIG. 1 and FIGS. 7(a), (b), operation of the vacuum processing device according to this embodiment will be explained next.

The load lock chamber 21 of the load lock mechanism 20, which carries the disk substrate 101 in and out of the main chamber 10, is formed by the space divided hermetically in a vacuum state with the hollowed inner wall 12b of the thick top plate 12, the lock opening lid member 22 opening and closing the outer side thereof, and the susceptor 57 at the inner side thereof. A pair of lock opening lid members 22 are mounted on both ends of the rotatable disk-carrying arm 23 respectively, and hermetically fitted to the load lock chamber 21 with flexibly removable mode by rotating the arm. As shown in FIG. 7(a), the lock opening lid member 22 is provided with a mechanism adsorbing the disk substrate 101, which adsorbs the disk substrate 101 conveyed after molded by a stamper machine at the bottom surface thereof and carries in the load lock chamber 21.

Under the condition that the load lock chamber 21 is open to the atmosphere side, the boundary thereof to the space of the main chamber 10 is sealed by the susceptor 57 pressed by the pusher 11 to prevent air from flowing in the main chamber. The lock opening lid member 22 delivers the disk substrate 101 to the susceptor 57 and the load lock chamber is hermetically sealed. Then, the load lock chamber 21 is evacuated by an exhaust system (not shown), and has a pressure equal to the atmosphere of the main chamber 10. In this condition, the pusher 11 is retracted, and the susceptor 57 is disconnected from the load lock chamber and returns to the predetermined position of the carrying table 50.

The pushers 11 corresponding to the film-depositing chamber 30 and the cooling chamber 40 move up and down in synchronization with the vertical movement of the pusher of the load lock mechanism, so that all pushers rise and descend simultaneously. That is to say, because the susceptors 57 have the load lock chamber 21, the film-depositing chamber 30 and the cooling chamber 40 sealed off hermetically from the space of the main chamber while the pushers 11 are raised, carrying in and out the disk substrate 101, depositing each one layer and cooling the disk substrate are carried out in the load lock mechanism, in the film-depositing chamber 30 and in the cooling chamber 40 respectively.

After one tact time has finished, the susceptors 57 are separated from each chamber and return to the carrying table, then the carrying table 50 rotates to carry each disk substrate to the next chamber. For example, a disk substrate carried in the load lock chamber 21 is transported to the cooling chamber 40a, and a disk substrate cooled in the cooling chamber 40a is transported to the film-depositing chamber 30a. A disk substrate on which one layer film is deposited in the film-depositing chamber 30a is transported to the next cooling chamber 40b. Thereafter, film-depositing and cooling are repeated sequentially. The disk substrate carried again in the load lock chamber 21 is carried out of the main chamber by the load lock mechanism 20 in the condition that the inside of the chamber 21 sealed by the susceptor returns to the atmosphere, and carried to the next UV-cured overcoat layer-coating process.

FIG. 8 shows a modified example of the cooling mechanism in which the shaft of the pusher 11 has a cooling path 11c so as to cool the pusher cylinder 11b of the pusher in addition to the cooling plate 43. Because the pusher cylinder 11b comes into contact with the bottom portion of the susceptor when the susceptor 57 is pushed up by the pusher 11, the susceptor 57 is cooled. As a result, the holder 62 is cooled and the disk substrate 101 is cooled through both the front and the rear surfaces. Consequently, effective cooling can be executed.

FIG. 9 to FIG. 11 are other modified examples. FIG. 9 shows that the outer lid member 42 itself of the cooling chamber is a cooling member having a cooling liquid flowing passage 47 formed therein, where cooling liquid is supplied through the cooling liquid supply pipe 43a and discharged through the cooling liquid discharge pipe 43b. FIG. 10 shows that the outer lid member 42 is provided with an outer heat-radiation fin 48a and an inner heat-radiation fin 48b inside the cooling chamber to cool the cooling chamber by forced air cooling from the outside. Though it is not shown in the figures above, it is preferable that cooling gas is introduced in the chamber. FIG. 11 shows that a feeding pipe 44a for an outer lid member cooling gas and a discharging pipe 44b for the cooling gas are provided so as to supply gas into the cooling chamber for heat-conducting from a processed object to be cooled.

As has been explained above, this embodiment is provided with a cooling chamber located between a load lock mechanism and a film-depositing chamber so that the processed object can be cooled in the cooling chamber while the object moves to the next processing stage. The action thereof will be explained hereinafter.

FIG. 12 illustrates the measurement result of the temperature for substrate processing in the film-depositing chambers 30a to 30d and the cooling chambers 40a to 40e in the case of fabricating an optical disk by depositing a multilayer film shown in FIG. 16. The sample was prepared as follows: A ZnS—SiO₂ dielectric material layer 102 was deposited by sputtering in the first film-depositing chamber 30a, and then it was cooled. Thereafter, the layer passed through sequentially and alternately each film-depositing chamber and each cooling chamber so as to layer a writing film 103, a ZnS—SiO₂ dielectric material film 104 and a silver (Ag) metal reflection layer 105. Because the substrate is maintained at a temperature of 50 degrees Celsius or less over the entire steps of the vacuum processing, the tilt of the optical disk can be suppressed.

As shown in Table 1, influence on the tilt of the disk substrate is deterioration of the rate of acceptable products due to generation of irreversible distortion in the substrate at a temperature above 70 degrees Celsius. Distortion is reversible at 70 degrees Celsius or less, and the tilt becomes hard to be generated at an ordinary temperature. Because there is no possibility of distortion remaining in the substrate at 50 degrees Celsius or less, width of temperature rising can have some margin. In consequence, sputtering time can be shortened by increasing the sputtering input power. Thereby, the tact time can be shortened.

TABLE 1

| Temperature (t) of the | |
|---|---|
| processed object | Condition of the tilt |
| 70° C. < t | Deformation by sputtering is not |
| | recovered. |
| 50° C. ≦ t < 70° C. | Deformation by sputtering is |
| | recovered. |
| t ≦ 50° C. | Sputtering rate can be raised. |

When the disk substrate carried to the load lock mechanism is a polycarbonate synthetic resin substrate shortly after molded by a stamper machine of the preceding process, the substrate itself is in the condition heated up to a temperature higher than the room temperature. Therefore, if the substrate in the condition of a high temperature is transported to the first film-depositing chamber 30a, the temperature thereof further rises during sputtering and the condition of film-depositing is deteriorated.

Upon disposing the first cooling chamber 40a between the load lock mechanism 20 and the first film-depositing chamber 30a in this embodiment, an appropriate film can be obtained by controlling and decreasing once the temperature of the substrate. If the temperature of the substrate is sufficiently controlled before load lock, the cooling chamber can be blank or omitted.

The cooling chambers 40b to 40d interposed between respective film-depositing chambers decrease the temperature of the substrate heated up due to each film-depositing to 50 degrees Celsius or less, and diminish the stress generated between the substrate and the multilayer film, so that generation of the tilt after fabrication is suppressed.

The cooling chamber 40e between the final film-depositing chamber 30d and the load lock chamber 20 is to prevent any distortion in the substrate from being generated due to rapid cooling caused by coming into contact with the atmosphere and to buffer lowering of the temperature of the substrate when the substrate heated up in the film-depositing chamber 30d is carried out in the atmosphere via the load lock mechanism. When the temperature of the substrate is sufficiently controlled after the substrate has been carried out from the load lock just as the substrate is carried in the load lock, this cooling chamber can be blank or omitted.

In accordance with this embodiment as mentioned above, the temperature of the processed substrate can be maintained to be 50 degrees Celsius or less, so that the tilt or deformation required for an optical disk having a multilayer film can be sufficiently suppressed. Furthermore, this embodiment can be applied to not only the optical disk but also optical components such as the optical interference filter composed of a multilayer film.

FIG. 13 and FIG. 14 show other embodiments of the present invention, in which the centers of the film-depositing chambers 70 and the load lock chamber 71 are located on a first circumference c1 centered at the rotating shaft 81 of the horizontal rotary carrying table, and the centers of the cooling chambers 90 are located at an equal angular interval on a second circumference c2 whose diameter is different from that of c1. The centers of the film-depositing chambers 70, the load lock chamber 71 and the cooling chambers 90 are coincident with the center of the susceptor connected to each chamber respectively.

The diameter of the second circumference c2 is smaller than that of the first circumference c1 in the case of FIG. 13, and the diameter of the second circumference c2 is greater than that of the first circumference c1 in the case of FIG. 14. Because the first circumference c1 for the arrangement of film-depositing chambers in both the structures above can be reduced as compared with the case in which film-depositing chambers and cooling chambers are arranged on an equal circumference, downsizing of the vacuum processing device can be achieved. The diameter of the cooling chamber can be formed to be the content slightly larger than 120 mm if the disk substrate is the DVD disk of 120 mm in diameter. However, because the film-depositing chamber requires the target having a larger diameter than the substrate in order to obtain uniformity of the multilayer film deposited on the substrate by sputtering, the film-depositing chamber occupies an area having a diameter larger than twice the diameter of the substrate. In consequence, by making the diameter for arrangement of the smaller-sized cooling chambers be different from the diameter for arrangement of the film-depositing chambers, it can be facilitated that the cooling chambers are arranged between the film-depositing chambers even though the interval between the chambers is narrowed down. Therefore, the diameter of the space in which the carrying table of the main chamber rotates can be reduced in comparison with the case of an equal diameter, so that the volume of the exhaust system of the main chamber can be diminished.

FIG. 15 shows a structure of the horizontal rotary-carrying table 80 when the circumference on which the cooling chambers 90 are arranged is different from the circumference on which the film-depositing chambers 70 and the load lock chamber 71 are arranged as shown in FIG. 13 and FIG. 14. The susceptor 82 is movable in the direction of radius of the table centered on the rotating shaft 81 like the dotted arrow shown in the figure, the opening 83 which the pusher penetrates is formed as an elongated hole. In compliance with intermittent rotation of the table, each susceptor changes alternately the position thereof from the second circumference c2 to the first circumference c1. This position change can be achieved by providing a guide or by driving each susceptor with a driving source.

In a vacuum processing device comprised of a load lock chamber and four film-depositing chambers, a vacuum processing device having a structure in which cooling mechanisms are disposed between respective film-depositing chambers has been described in the embodiments mentioned heretofore. However the present invention is not restricted to a device having four film-depositing chambers, but applicable to a device having a plurality of processing chambers.

Moreover, a film-depositing chamber having an evaporating source by an electron beam not a discharge sputtering source can be included in a part of the film-depositing chamber.

Though explanation for a mask of a disk-like processed object has been omitted, the present invention can be applied to all processed objects regardless of the presence or absence of the mask.

In addition, the present invention can be also applied to an optical component having a multilayer film deposited on a thin glass substrate whose distortion is affected by depositing of the multilayer film as the processed object, as well as a multilayer-deposited synthetic resin substrate like an optical disk.

### BRIEF DESCRIPTION OF THE DRAWINGS

FIG. 1 is a schematic plan view showing an embodiment of the present invention.

FIG. 2 is a schematic cross sectional view showing FIG. 1 cut at the line A-A.

FIG. 3 is a schematic plan view of the horizontal rotary carrying table of the embodiment.

FIG. 4 is a cross sectional view showing the cooling mechanism of the embodiment.

FIG. 5 is a cross sectional view explaining operation of the cooling mechanism of the embodiment.

FIG. 6 is a cross sectional view explaining operation of the cooling mechanism of the embodiment.

FIGS. 7 (a) and (b) are schematic diagrams explaining operation of the embodiment.

FIG. 8 is a cross sectional view showing a modified example of the cooling mechanism.

FIG. 9 is a cross sectional view showing a modified example of the cooling mechanism.

FIG. 10 is across sectional view showing a modified example of the cooling mechanism.

FIG. 11 is a cross sectional view showing a modified example of the cooling mechanism.

FIG. 12 is a diagram of curve showing the temperature of the processed object of the embodiment during film-depositing.

FIG. 13 is a schematic plan view showing another embodiment of the present invention.

FIG. 14 is a schematic plan view showing another embodiment of the present invention.

FIG. 15 is a schematic plan view of the horizontal rotary carrying table applied for another embodiment of the present invention.

FIG. 16 is a partly magnified schematic cross-sectional view of an optical disk substrate.

FIG. 17 (a) is a schematic plan view of a conventional device, and (b) is a schematic cross sectional view along the line A-A of (a).

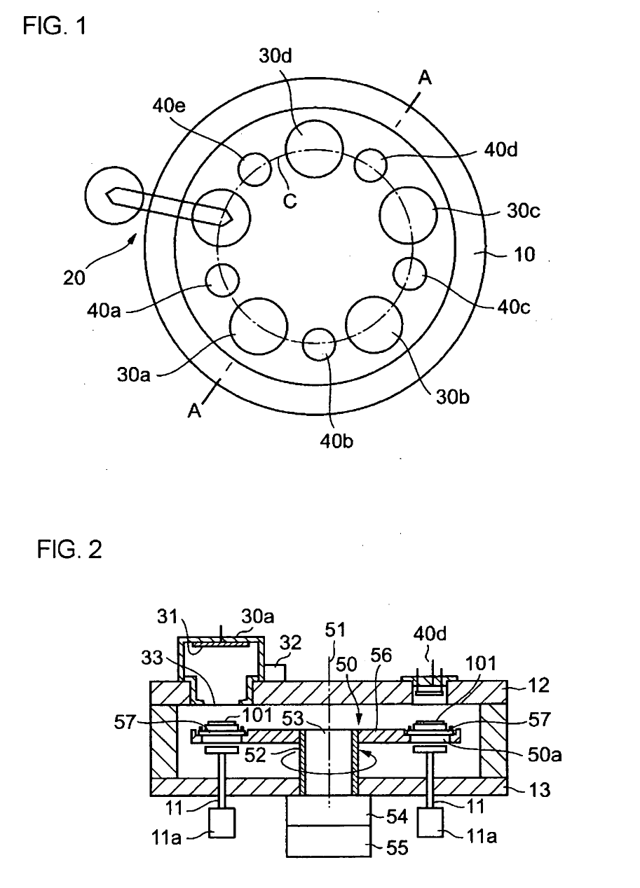

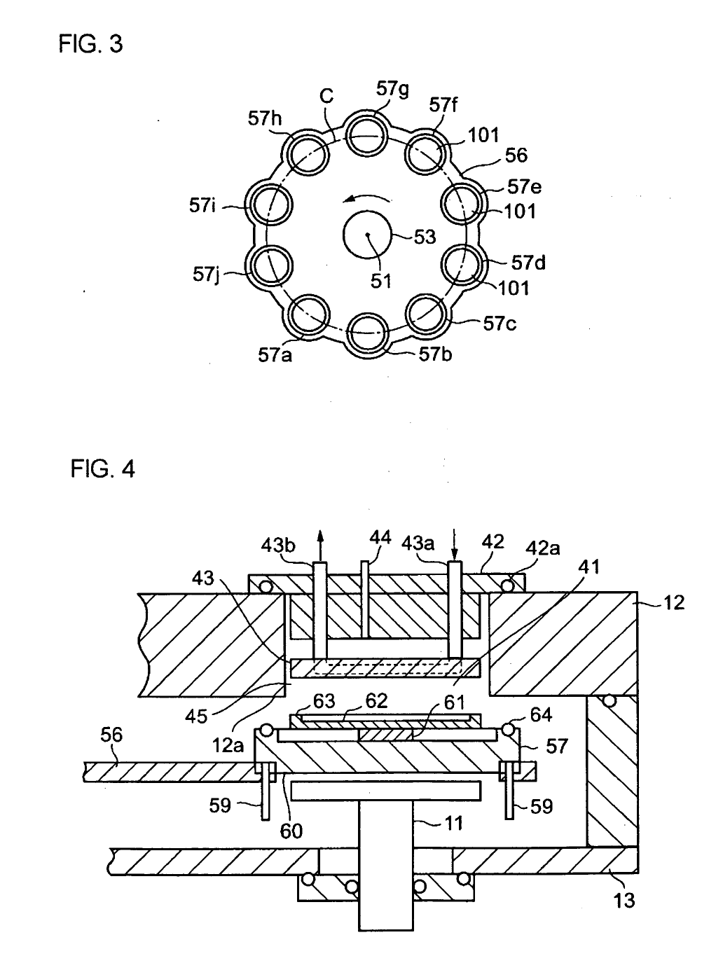

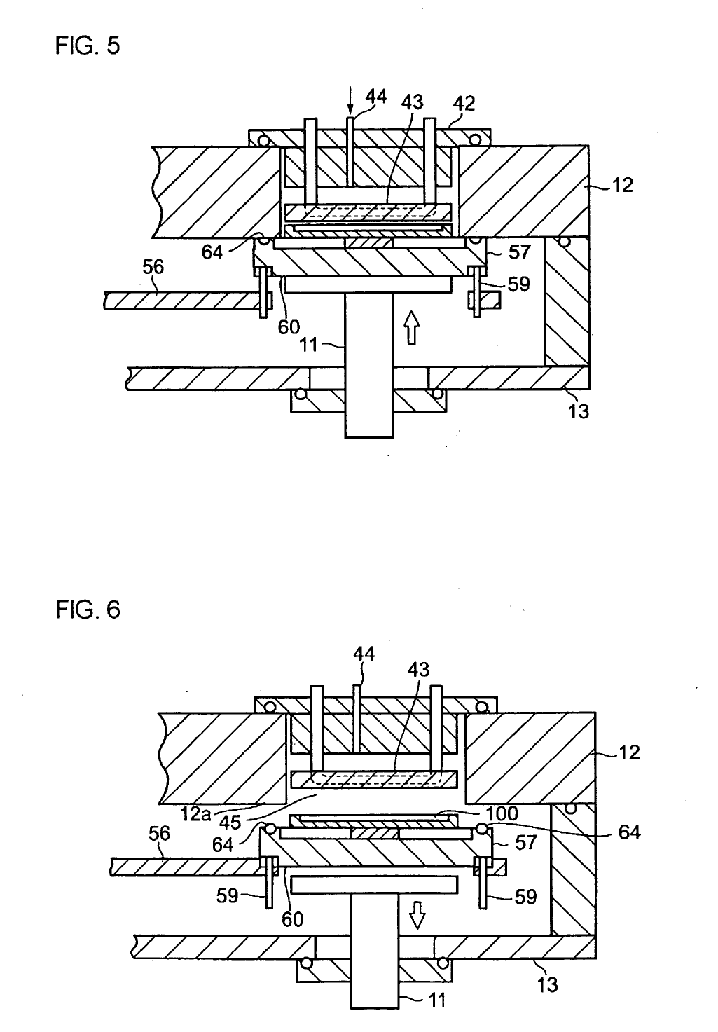

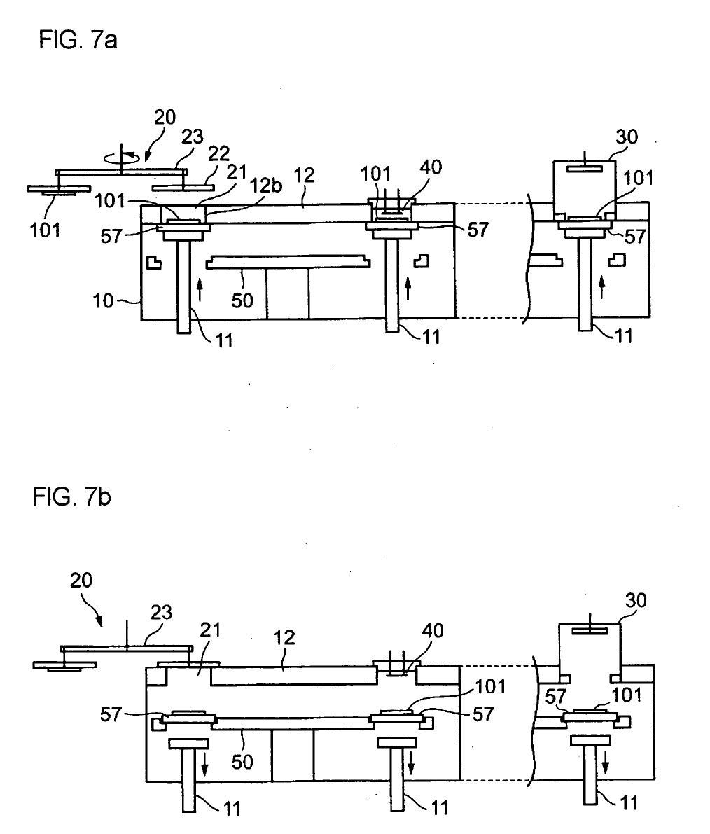

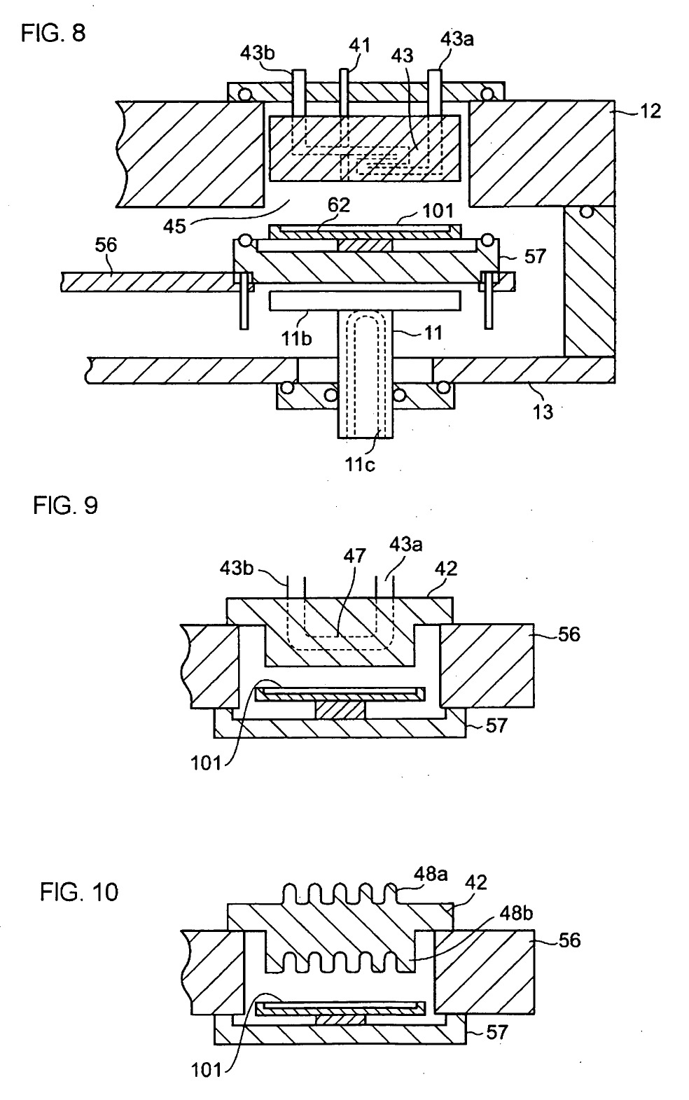

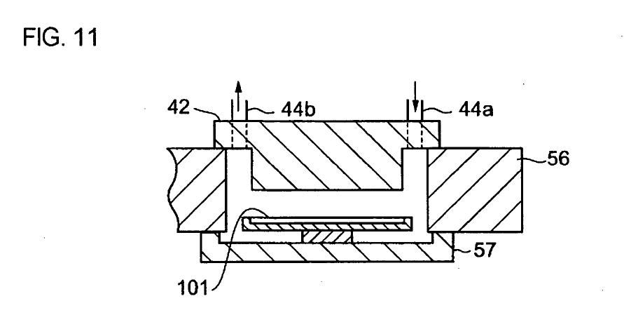

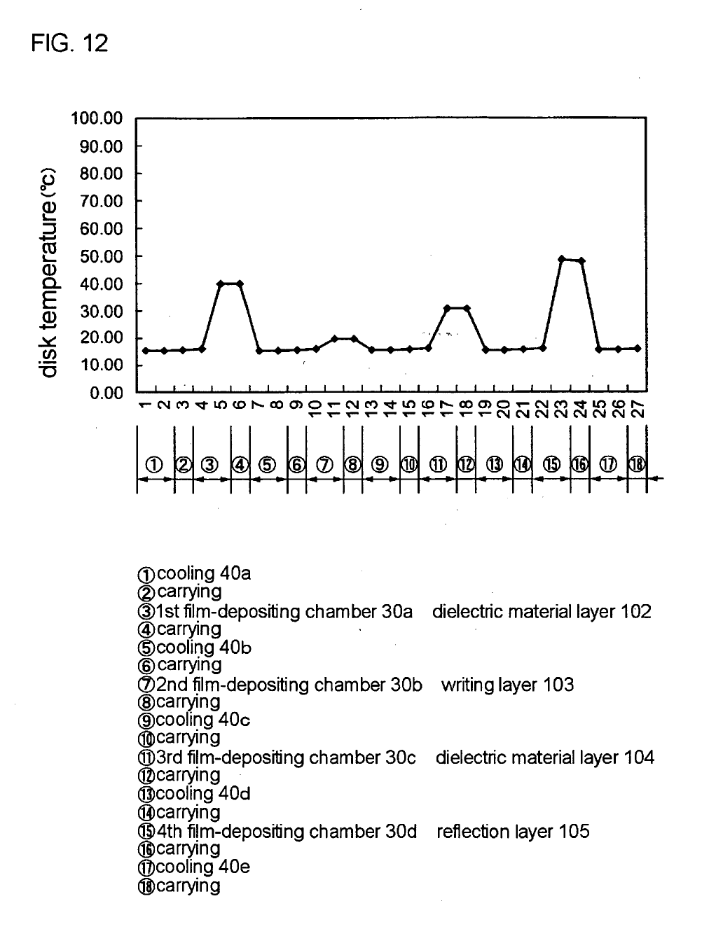

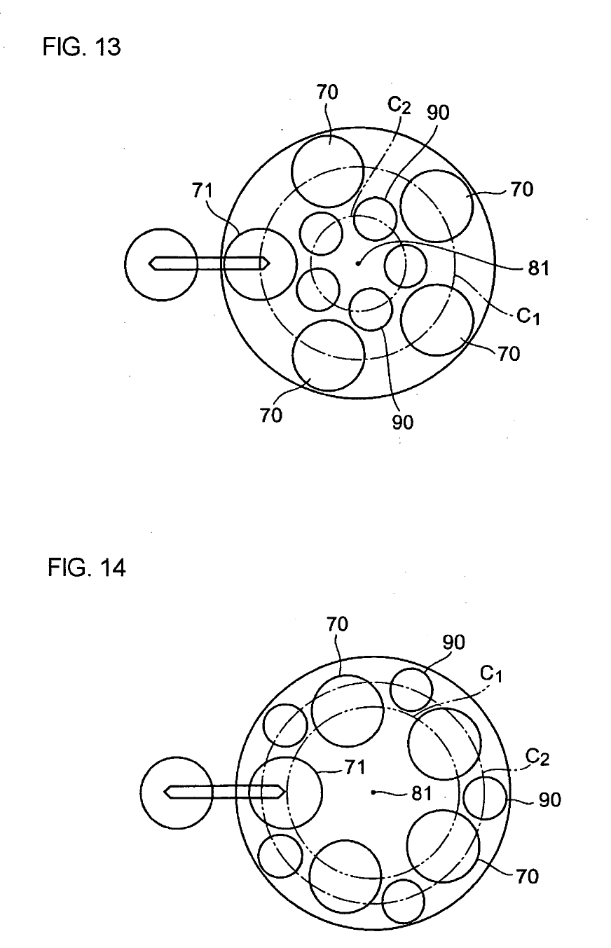

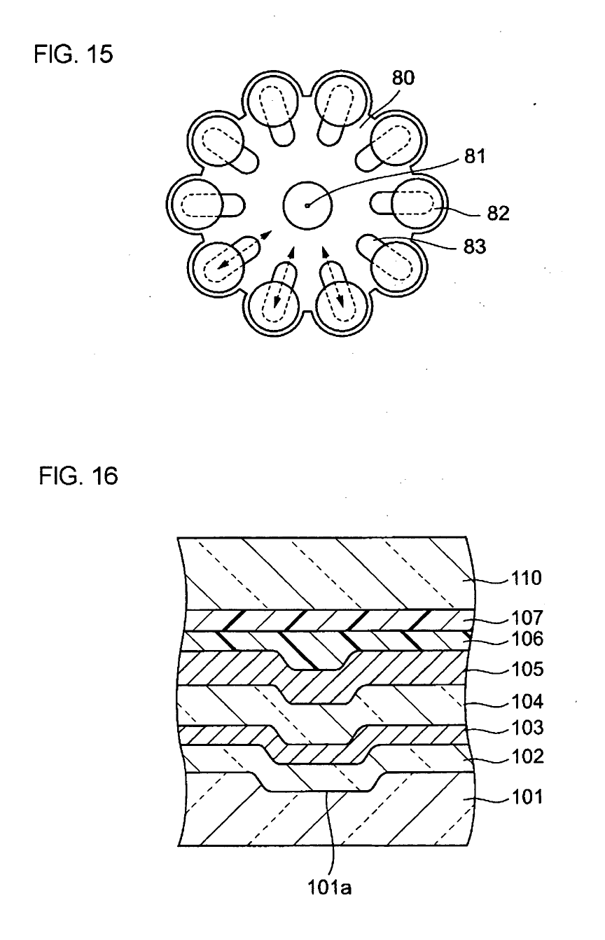

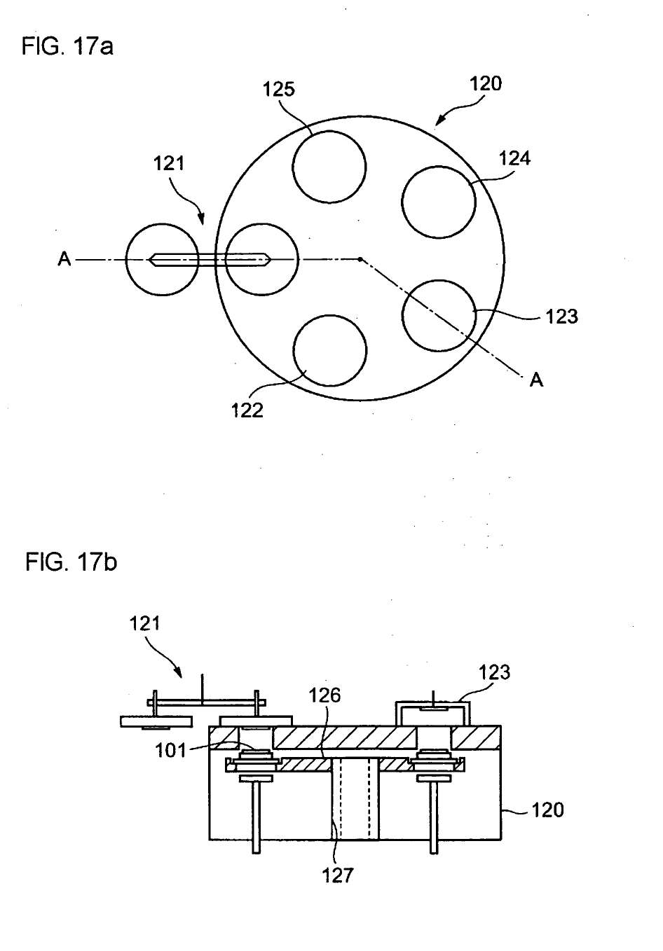

### EXPLANATION OF THE MARKS

10: Main chamber
11: Pusher
20: Load lock mechanism
30 (30a to 30d): Film-depositing chamber
40 (40a to 40e): Cooling chamber (Cooling mechanism)
50: Horizontal rotary carrying table
51: Axis
52: Rotating shaft
56: Table base member
(57a to 57j): Susceptor
43: Cooling plate (Cooling member)
44: Cooling gas supplying pipe
101: Disk substrate (Processed object)

1. A vacuum processing device comprising:
a main chamber being evacuated in a vacuum state;
a load lock mechanism carrying a processed object into and out of the main chamber while holding the vacuum state of the main chamber;
a rotary carrying table disposed in the main chamber, and forming a carrying route for the processed object;
a plurality of film-depositing chambers for depositing a film in a multilayer-shape on the processed object, disposed in the main chamber along a circumference about the rotating shaft; and
cooling mechanisms disposed between respective film-depositing chambers, and cooling the processed object.

2. The vacuum processing device as set forth in claim 1, wherein the cooling mechanism is disposed between the load lock mechanism and the film-depositing chamber.

3. The vacuum processing device as set forth in claim 1, wherein when the carrying route is a trace of the center of the processed object to be carried, the carrying route by rotation of the horizontal rotary carrying table traces a certain circle, and the load lock mechanism, the film-depositing chamber and the cooling mechanism are disposed at an interval of a certain angular distance about the rotating shaft along the circle.

4. The vacuum processing device as set forth in claim 1, wherein the film-depositing chambers are disposed on a first circumference with a central portion thereof at the rotating shaft of the rotary carrying table, and the cooling mechanisms are disposed on a second circumference, the second circumference being different from the first circumference with respect to radii thereof.

5. The vacuum processing device as set forth in claim 4, wherein a susceptor carrying the processed object is disposed on the rotary carrying table, and the susceptor is movable between the first circumference and the second circumference on the rotary carrying table in a radial direction thereof.

6. The vacuum processing device as set forth in claim 1, wherein the cooling mechanism comprises a cooling chamber.

7. The vacuum processing device as set forth in claim 6, wherein an area occupied by one of the cooling chambers in the main chamber is smaller than an area occupied by one of the film-depositing chamber.

8. The vacuum processing device as set forth in claim 6, wherein the cooling mechanism is provided with a cooling chamber, and capable of isolating hermetically from a space of the main chamber.

9. The vacuum processing device as set forth in claim 8, wherein a susceptor carrying the processed object is disposed on the rotary carrying table, and the susceptor is lifted by a susceptor-pusher and pressed on an opening wall of the cooling chamber so as to come to be hermetically sealed.

10. The vacuum processing device as set forth in claim 8, wherein the cooling mechanism comprises an inlet portion introducing a gas into the cooling chamber and acting as a heat conducting member from the processed object.

11. The vacuum processing device as set forth in claim 6, wherein a cooling member having a cooling surface is provided in the cooling chamber.

12. The vacuum processing device as set forth in claim 1, wherein each of the cooling chambers is capable of setting a temperature individually.

13. The vacuum processing device as set forth in claim 1, wherein the processed object having a film deposited by the film-depositing chamber is a disk-like processed object having a substrate of synthetic resin.

14. A manufacturing method of an optical disk, wherein a multilayer film is obtained by depositing continuously sputter-deposited films on a disk substrate of synthetic resin upon executing a plurality of sputtering processes in an evacuated atmosphere, and a cooling process is inserted between all the sputtering processes in order to maintain a temperature of the substrate to be 50 degrees Celsius maximum.

15. The vacuum processing device as set forth in claim 2, wherein the cooling mechanism comprises a cooling chamber.

16. The vacuum processing device as set forth in claim 15, wherein an area occupied by one of the cooling chambers in the main chamber is smaller than an area occupied by one of the film-depositing chamber.

17. The vacuum processing device as set forth in claim 15, wherein the cooling mechanism is provided with a cooling chamber, and capable of isolating hermetically from a space of the main chamber.

18. The vacuum processing device as set forth in claim 17, wherein a susceptor carrying the processed object is disposed on the rotary carrying table, and the susceptor is lifted by a susceptor-pusher and pressed on an opening wall of the cooling chamber so as to come to be hermetically sealed.

19. The vacuum processing device as set forth in claim 17, wherein the cooling mechanism comprises an inlet portion introducing a gas into the cooling chamber and acting as a heat conducting member from the processed object.

20. The vacuum processing device as set forth in claim 15, wherein a cooling member having a cooling surface is provided in the cooling chamber.
